(19) United States
(12) Patent Application Publication
(10) Pub. No.: US 2016/0118540 A1
(43) Pub. Date: Apr. 28, 2016

(54) Light-Emitting Diode

(71) Applicant: TIANJIN SANAN OPTOELECTRONICS CO., LTD., Tianjin (CN)

(72) Inventors: MU-SEN DONG, Tianjin (CN); LI-YING SHEN, Tianjin (CN); DU-XIANG WANG, Tianjin (CN); CHAO-YU WU, Tianjin (CN); LIANG-JUN WANG, Tianjin (CN)

(73) Assignee: TIANJIN SANAN OPTOELECTRONICS CO., LTD., Tianjin (CN)

(21) Appl. No.: 14/735,513

(22) Filed: Jun. 10, 2015

(30) Foreign Application Priority Data
Oct. 28, 2014 (CN) 201410584482.X

(51) Int. Cl. H01L 33/32; H01L 33/10; H01L 33/00; H01L 33/06; H01L 33/24

(52) U.S. Cl. CPC H01L 33/32; H01L 33/06; H01L 33/24; H01L 33/0025; H01L 33/10

(57) ABSTRACT

A light-emitting diode includes at least an N-type layer, a light-emitting layer and a P-type layer, wherein the light-emitting layer forms a “V”-shaped indentation or pit during epitaxial process and the V pit is filled in with at least one type of metal nanoparticles to generate surface plasma coupling effect and to improve recombination probability of holes and electrons, thus improving internal quantum efficiency; further, a V pit is generated in the N-type layer during epitaxial process; surface plasma coupling effect is generated by filling metal nanoparticles in the V pit to increase light reflection, light extraction efficiency and external quantum efficiency, thereby improving light emitting efficiency of LED; and the V pit is formed directly by adjusting growth rate, thickness, temperature, pressure or doping during epitaxial process instead of etching, which causes no damage to the LED epitaxial layer, thus simplifying process and improving device stability.

### CROSS-REFERENCE TO RELATED APPLICATIONS

The present application is a continuation of, and claims priority to, Chinese Patent Application No. CN 201410584482.X filed on Oct. 28, 2014, the disclosure of which is hereby incorporated by reference in its entirety.

### BACKGROUND

As the light-emitting diode (LED) expands its application, how to improve its light emitting efficiency becomes a key study point in industry. The Chinese Patent CN101950785A discloses a P-type GaN layer structure with GaN-based LED die, in which, holes are arranged over the P-type GaN layer. The hole bottom is about 10-100 nm far from the quantum well active region of the LED die. The holes are filled in with metal particles and the openings are filled in with a transparent dielectric layer film for blocking metal particles. The internal quantum efficiency (IQE) of the light-emitting diode can be improved through coupling effect between the surface plasmon polarition and quantum well light-emitting layer. In that patent, the metal nanoparticles are within the P-type layer. In theory, the shorter distance between the metal nanoparticles and the light-emitting layer is, the higher is the coupling efficiency and the higher is the LED light emitting efficiency. Therefore, it is necessary to provide a device structure of simple process, which causes no damage to the LED epitaxial layer and shortens distance between the metal nanoparticle layer and the light-emitting layer, so as to further improve light emitting efficiency of the light-emitting diode.

### SUMMARY

The present disclosure provides a light-emitting diode of simple and etching-free process, which causes no damage to the epitaxial layer and shortens distance between the metal nanoparticle layer and the light-emitting layer, so as to further improve light emitting efficiency of the light-emitting diode.

A light-emitting diode is provided, comprising: a substrate, a buffer layer, an N-type layer, a light-emitting layer, a P-type layer, a transparent conducting layer, an N electrode, a P electrode and an insulating protective layer, wherein: the light-emitting layer forms a V pit during epitaxial process and the V pit is filled in with at least one kind of metal nanoparticles; further, the N-type GaN layer forms a V pit during epitaxial process and the V pit is filled in with at least one kind of metal nanoparticles.

The N-type layer is N-type GaN layer, N-type AlN layer, N-type InN layer, N-type AlGaN layer, N-type InGaN layer, N-type AlInGaN layer or any of their combinations; and the P-type layer is P-type GaN layer, P-type AlN layer, P-type InN layer, P-type AlGaN layer, P-type InGaN layer, P-type AlInGaN layer or any of their combinations.

The light-emitting layer forms a V pit by adjusting growth rate, thickness, temperature, pressure or doping during epitaxial process. The V pit of the light-emitting layer is about 10-1000 nm, and its density is about 1×10⁷−1×10¹⁰/cm².

The N-type layer forms a V pit by adjusting growth rate, thickness, temperature, pressure or doping during epitaxial process. The V pit of the N-type layer is about 10-1000 nm, and its density is about 1×10⁷−1×10¹⁰/cm².

The metal nanoparticle is at least one of main group metal or metalloid. The diameter of the metal nanoparticle is about 1-100 nm and thickness is about 1-500 nm.

The LEDs can be used in light-emitting systems such as lighting systems or display systems. The LED of the present disclosure may have one or more of the advantages such as:

(1) Surface plasma coupling effect is generated by filling metal nanoparticles in the V pit of the light-emitting layer to inhibit coupling of electrons or holes with phonons and improve recombination probability of holes and electrons, thus improving internal quantum efficiency; and higher coupling efficiency and internal quantum efficiency are achieved in comparison to filling metal nanoparticles in the P-type layer.

(2) Surface plasma coupling effect is generated by filling metal nanoparticles in the V pit of the N-type layer to increase light reflection, light extraction efficiency and external quantum efficiency, thereby improving light emitting efficiency of the LED.

(3) The V pit is formed directly by adjusting growth rate, thickness, temperature, pressure or doping during epitaxial process instead of etching, which causes no damage to the LED epitaxial layer, thus simplifying process and improving device stability.

### BRIEF DESCRIPTION OF THE DRAWINGS

FIG. 1 is a diagrammatic cross section of the light-emitting diode according to Embodiment 1 of the present disclosure.

FIG. 2 is a diagrammatic cross section of the light-emitting diode according to Embodiment 2 of the present disclosure.

FIG. 3 is a diagrammatic cross section of the light-emitting diode according to Embodiment 3 of the present disclosure.

In the drawings:

100: substrate; 101: buffer layer; 102: N-type layer; 103: MQW light-emitting layer; 104: P-type layer; 105: transparent conducting layer; 106a/106b/106c: V pit; 107a/107b/107c: metal nanoparticles; 108: N electrode; 109: P electrode; 110: insulating protective layer.

### DETAILED DESCRIPTION

The light-emitting diode in the preferable embodiment of the present disclosure will be described in detail below with reference to the drawings.

### Embodiment 1

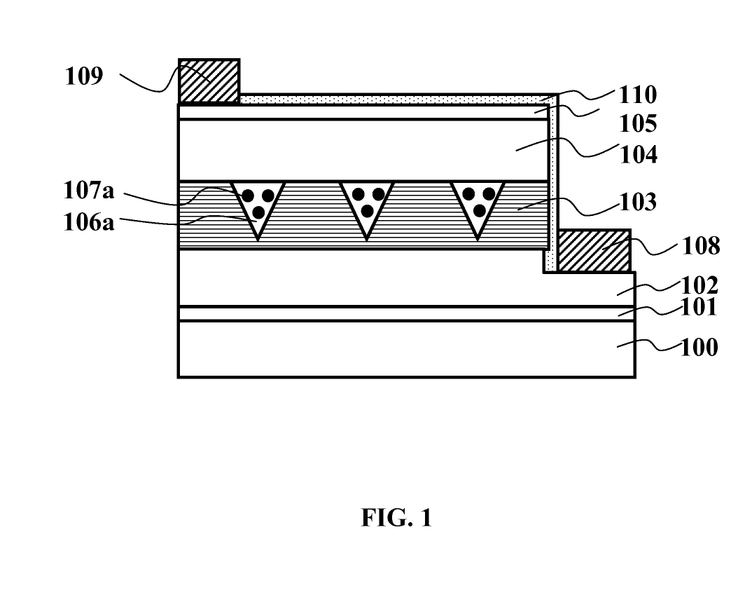

As shown in FIG. 1, a light-emitting diode, comprising, from bottom to up:

(1) a substrate 100, like sapphire (Al₂O₃), SiC, Si or GaN. This embodiment preferably adopts sapphire substrate;

(2) a buffer layer 101 over the substrate 100 after high temperature treatment; the buffer layer is a 5-50 nm thick gallium nitride (GaN) and/or an aluminum nitride (AlN) layer grown under 400-600° C.;

(3) a 10-10000 nm thick N-type layer 102 (in this embodiment, preferably, N-type GaN layer) over the buffer layer 101 grown at 0.1-10 μm/h rate under 800-1200° C. and 100-700 torr; and the doping source is preferably SiH₄ with doping concentration of 1×10¹⁸−1×10²¹ cm⁻³;

(4) a MQW light-emitting layer 103 over the N-type layer 102; the MQW light-emitting layer 103 is laminated by (InₓGa₁₋ₓN/GaN)ₙ periodic well layer/cladding layer at 0.01-1 μm/h under 600-900° C. and 100-700 torr, in which, the periodic number n is 2 - 2-100 and preferably 5-10; the InₓGa₁₋ₓN well layer is about 1-100 nm thick, and In component 0<x<1; and the GaN cladding layer is about 5-100 nm thick, which is non-doping or N-type doping, wherein, N-type doping concentration is 1×10¹⁶−1×10²⁰ cm⁻³ and the doping source is preferably SiH₄. A V pit 106a is formed by adjusting growth rate, thickness, temperature, pressure or doping of the MQW light-emitting layer 103 well layer/cladding layer. The V pit 106a in the MQW light-emitting layer 103 is about 10-1000 nm and the density is about 1×10⁷−1×10¹⁰/cm². At least one kind of metal nanoparticles 107a is filled in the V pit 106a, wherein, the metal nanoparticle 107a is at least one of main group metal or metalloid with particle diameter of 1-100 nm and thickness of 1-500 nm;

(5) a 50-300 nm P-type layer 104 (in this embodiment, preferably, P-type GaN layer) over the MQW light-emitting layer 103 grown under 900-1000° C.; and the doping source is preferably CP₂Mg with doping concentration of 1×10¹⁹−1×10²¹ cm⁻³;

(6) a transparent conducting layer 105, either transparent conducting oxide layer or nitride layer, over the P-type layer 104; and this embodiment preferably adopts indium tin oxide (ITO);

(7) an N electrode 108 over the partially-exposed N-type layer 102 through etching;

(8) a P electrode 109 over the transparent conducting layer 105; and

(9) an insulating protective layer 110 over the light-emitting diode surface for protecting the light-emitting diode.

### Embodiment 2

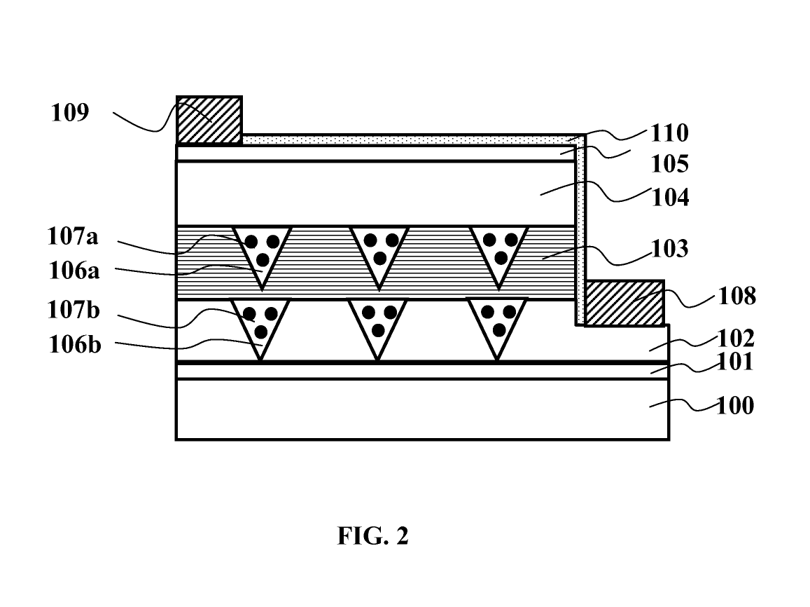

As shown in FIG. 2, a light-emitting diode is provided. Different from Embodiment 1, further, in step (3), the N-type layer 102 forms a V pit during epitaxial process and the V pit at least is filled in with a kind of metal nanoparticles. A V pit 106b is formed in the N-type layer by adjusting growth rate, thickness, temperature, pressure or doping of the N-type layer 102. The V pit 106b in the N-type layer is about 10-1000 nm and the density is about 1×10⁷−1×10¹⁰/cm². At least one kind of metal nanoparticles 107b is filled in the V pit 106b, wherein, the metal nanoparticle 107b is at least one of main group metal or metalloid with particle diameter of 1-100 nm and thickness of 1-500 nm.

### Embodiment 3

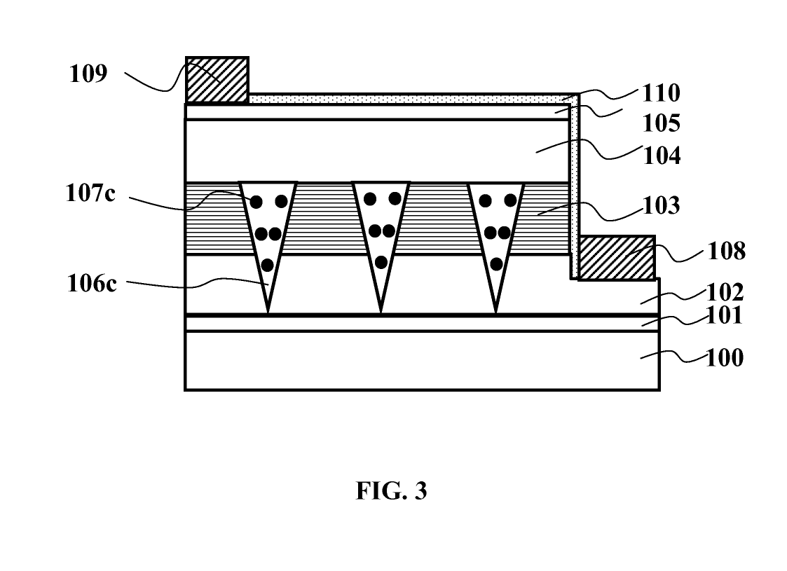

As shown in FIG. 3, a light-emitting diode is provided. Different from Embodiment 2, in steps (3) and (4), a V pit 106c is formed throughout the N-type layer 102 and MQW light-emitting layer 103 by adjusting growth rate, thickness, temperature, pressure or doping of the N-type layer 102 and the MQW light-emitting layer 103. The V pit 106c is about 10-1000 nm and the density is about 1×10⁷−1×10¹⁰/cm². At least one kind of metal nanoparticles 107c is filled in the V pit 106c, wherein, the metal nanoparticle 107c is at least one of main group metal or metalloid with particle diameter of 1-100 nm and thickness of 1-500 nm.

In the light-emitting diode fabricated as above, surface plasma coupling effect is generated by filling metal nanoparticles in the V pit of the MQW light-emitting layer to inhibit coupling of electrons or holes with phonons and improve recombination probability of holes and electrons, thus improving internal quantum efficiency; and higher coupling efficiency and internal quantum efficiency are achieved in comparison to filling metal nanoparticles in the P-type layer. Further, surface plasma coupling effect is generated by filling metal nanoparticles in the V pit of the N-type layer to increase light reflection, light extraction efficiency and external quantum efficiency, thereby improving light emitting efficiency of the light-emitting diode. And the V pit is formed during epitaxial process directly by adjusting growth rate, thickness, temperature, pressure or doping during epitaxial process instead of etching, which causes no damage to the LED epitaxial layer, thus simplifying process and improving device stability.

All references referred to in the present disclosure are incorporated by reference in their entirety. Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A light-emitting diode, comprising an N-type layer, a light-emitting layer, and a P-type layer, wherein at least one of the light-emitting layer or the N-type layer has one or more “V”-shaped indentations formed therein, and wherein the one or more “V”-shaped indentations have at least one type of metal nanoparticles disposed therein.

2. The light-emitting diode of claim 1, wherein the one or more “V”-shaped indentations are formed in the N-type layer.

3. The light-emitting diode of claim 1, wherein the one or more “V”-shaped indentations are formed through an epitaxial process.

4. The light-emitting diode of claim 3, wherein the one or more “V”-shaped indentations are formed by adjusting at least one of a growth rate, a thickness, a temperature, a pressure, or a doping during the epitaxial process.

5. The light-emitting diode of claim 1, wherein the one or more “V”-shaped indentations have a size of about 10-1000 nm.

6. The light-emitting diode of claim 1, wherein a density of the one or more “V”-shaped indentation is about 1×10⁷−1×10¹⁰/cm².

7. The light-emitting diode of claim 1, wherein the metal nanoparticles comprise at least one of a main-group metal or a metalloid, and wherein the light-emitting layer has one or more “V”-shaped indentations disposed therein.

8. The light-emitting diode of claim 7, wherein a diameter of the metal nanoparticles is about 1-100 nm, and wherein both the light-emitting layer and the N-layer have one or more “V”-shaped indentations disposed therein.

9. The light-emitting diode of claim 7, wherein a thickness of the metal nanoparticles is about 1-500 nm, and wherein the light-emitting layer and the N-layer have one or more “V”-shaped indentations disposed therethrough.

10. The light-emitting diode of claim 1, wherein the N-type layer comprises at least one of an N-type GaN layer, an N-type AlN layer, an N-type InN layer, an N-type AlGaN layer, an N-type InGaN layer, or an N-type AlInGaN layer; and wherein the P-type layer comprises at least one of a P-type GaN layer, a P-type AlN layer, a P-type InN layer, a P-type AlGaN layer, a P-type InGaN layer, or a P-type AlInGaN layer.

11. A light-emitting system comprising a plurality of light-emitting diodes (LED), each LED comprising an N-type layer, a light-emitting layer, and a P-type layer, wherein at least one of the light-emitting layer or the N-type layer has one or more “V”-shaped indentations formed therein, and wherein the one or more “V”-shaped indentations have at least one type of metal nanoparticles disposed therein.

12. The system of claim 11, wherein the one or more “V”-shaped indentations are formed in the N-type layer.

13. The system of claim 11, wherein the one or more “V”-shaped indentations are formed through an epitaxial process.

14. The system of claim 11, wherein the one or more “V”-shaped indentations are formed by adjusting at least one of a growth rate, a thickness, a temperature, a pressure, or a doping during the epitaxial process.

15. The system of claim 11, wherein the one or more “V”-shaped indentations have a size of about 10-1000 nm.

16. The system of claim 11, wherein a density of the one or more “V”-shaped indentations is about 1×10⁷−1×10/cm².

17. The system of claim 11, wherein the metal nanoparticles comprise at least one of a main-group metal or a metalloid, and wherein the light-emitting layer has one or more “V”-shaped indentations disposed therein.

18. The system of claim 17, wherein a diameter of the metal nanoparticles is about 1-100 nm, and wherein both the light-emitting layer and the N-layer have one or more “V”-shaped indentations disposed therein.

19. The system of claim 17, wherein a thickness of the metal nanoparticles is about 1-500 nm, and wherein the light-emitting layer and the N-layer have one or more “V”-shaped indentations disposed therethrough.

20. The system of claim 11, wherein the N-type layer comprises at least one of an N-type GaN layer, an N-type AlN layer, an N-type InN layer, an N-type AlGaN layer, an N-type InGaN layer, or an N-type AlInGaN layer; and wherein the P-type layer comprises at least one of a P-type GaN layer, a P-type AlN layer, a P-type InN layer, a P-type AlGaN layer, a P-type InGaN layer, or a P-type AlInGaN layer.
